(19) United States
(12) Patent Application Publication
(10) Pub. No.: US 2012/0162918 A1
(43) Pub. Date: Jun. 28, 2012

(54) Passive Cabinet Cooling

(75) Inventors: Tomas Thyni, Jarfalla (SE); Mats Forsman, Ronninge (SE); Johan Meyer, Ronninge (SE)

(73) Assignee: Telefonaktiebolaget LM Ericsson (publ), Stockholm (SE)

(21) Appl. No.: 13/393,859

(22) PCT Filed: Jan. 22, 2010
(86) PCT No.: PCT/SE2010/050057

§ 371 Date: Mar. 16, 2012

Related U.S. Application Data
(60) Provisional application No. 61/257,206, filed on Nov. 2, 2009.

(51) Int. Cl. H05K 7/20

(52) U.S. Cl. 361/698; 361/689; 361/700

(57) ABSTRACT

An arrangement and a method for transferring surplus heat away from electronic components. An arrangement (300) at a rack (302) for transfering surplus heat away from at least one heat generating electronic component arranged in the rack (302) is provided. At least one heat-pipe (304) is arranged adjacent to the electronic component (s), the heat-pipe (s) containing a self-circulating cooling medium which in use, absorbs heat from the electronic component (s) and transports the heat by self-circulation away from the electronic component(s) through the heat-pipe(s) (304). By arranging heat-pipes at racks/cabinets comprising electronic equipments, surplus heat from the equipments can be transferred away in an efficient way, without supplying additional energy for the transferring. In addition, the surplus heat can be taken care of for other purposes, e.g. for warming up buildings, which further decreases the needs for additional energy.

### TECHNICAL FIELD

The present invention relates generally achieving reliable working conditions for electronic components. In particular, the present invention can be used for transferring surplus heat away from network components arranged in a cabinet.

### BACKGROUND

With the emergence of information technology, networking components handles traffic more efficiently per transported bit, but the traffic per network node increases even more. This results in that the new network nodes require more power and that the total power consumption per node increases. Network components are commonly arranged in cabinets or racks. 80-90% of the energy used by the network components will generate heat. To get good MTBF (Mean-Time Between Failure) on the nodes in a cabinet the air in the cabinet must be kept cool and any heat generated must be efficiently vented out.

High capacity network components have a power consumption of about 10 kW, and are arranged in cabinets.

Today, there exists some methods for cooling electronic components, e.g. active cabinet cooling solutions which ventilates heat away from the electronic components by fans, or supplies pre-cooled air to the electronic components. However, such methods requires a lot of energy for cooling down the air to be supplied, or driving the fans to keep the cabinet cool. Such fans are typically noisy, which may be percieved annoying.

There are also passive cabinet cooling systems using natural airflow and chimneys, but they have limited cooling capacity, and the air inside the cabinet can get fairly hot in the top of the cabinet. The patent publications U.S. Pat. No. 6,691,766 B1, and U.S. Pat. No. 5,884,693 A describes two cooling systems. However, they need access to the ground for transporting the surplus heat away.

Usually, surplus heat is ventilated away from racks comprising electronic equipment, as illustrated in FIG. 1. In an arrangement 100 comprising a rack 102, a ventilation air stream (not shown) is typically performad by a fan 104. Alternatively, pre-cooled air will be supplied to the rack 102 or the environment of the rack 102, the air being pre-cooled by an aggregate 106.

Another method for transferring surplus heat away from a rack 202 comprising electronic equipment is shown in FIG. 2. The arrangement 200 comprises the rack 202 which is surrounded by a stream of a cooling medium 204. The cooling medium 204 absorbs the surplus heat and transfers it to the ground 206, where the cooling medium 204 is cooled down by the lower temperature of the ground. To achieve the circulation of the cooling medium 204, a pump 208 is employed for pumping the cooling medium 204. Alternatively, one or more one-way valves 210 are applied for achieving the circulation of the cooling medium 204.

In view of the prior art, there is a need for a method of transfering surplus heat away from electronic components which requires less energy, without decreasing the heat being transferred away.

### SUMMARY

It is an object to adress at least some of the problems outlined above. In particular, it is an object to achieve a relatively efficient transfering of surplus heat away from electronic components, without requiring a lot of energy to transport the heat away. These objects and others may be achieved primarily by a solution according to the attached independent claims.

The term “heat-pipe” is used throughout this description to denote a closed pipe comprising a cooling medium. Typically, a heat pipe is arranged for transporting heat from a hot-spot to a cooling flange, where the heat may be ventilated from the heat-pipe. At the hot-spot, the heat is absorbed by the heat-pipe, and the heat will evaporise the cooling medium which will be transported to a cooling flange, i.e. the cooling medium changes phase from liquid to gas. At the cooling flange the cooling medium will then be cooled down and condensate, i.e. the cooling medium will return from gas to liquid. The cooling media is then transported to the hot-spot for being further evaporised. Common cooling medias employed in heat-pipes are water, carbon dioxide, ammonia, acetone, nitrogen, methanol, and sodium, etc.

With the term “rack” is in this description meant any suitable arrangement of electronic components in a rack, frame, support, or cabinet.

The term “electronic component” is used to define any electronic component, or equipment arranged in a rack, and which generates surplus heat, e.g. cards in a base station in a mobile communication network, or computer servers in a server room, etc.

According to one aspect, an arrangement at a rack is provided for transfering surplus heat away from at least one heat generating electronic component arranged in the rack. The arrangement comprises at least one heat-pipe arranged adjacent to the electronic component(s), wherein the heat-pipe(s) contain a self-circulating cooling medium which in use, absorbs heat from the electronic component(s) and transports the heat by self-circulation away from the electronic component(s) through the heat-pipe(s). The heat-pipe(s) may be arranged substantially vertical, to utilise the gravitational force for circulating the cooling medium in the heat-pipe(s). Furthermore, the heat-pipe(s) may be selected as straight, looped, or any combination of straight and looped ones.

According to another embodiment a method for for transferring surplus heat away from at least one electronic component arranged in a rack is provided. The method comprises: absorption of surplus heat from the electronic component(s) by at least one heat-pipe; evaporisation of a cooling medium contained in the heat-pipe(s); transportation of the evaporised cooling medium from the electronic component(s) to a heat conveying element by self-circulation; condensation of the evaporised cooling medium at the heat conveying element and conveyance of the surplus heat to an environment outside the rack; and transportation of the condensated cooling medium to the electronic component(s) by self-circulation to further absorb surplus heat.

By arranging traditional heat-pipes or looped-heat-pipes integrated in the rack/cabinet the heat generated inside the rack/cabinet can be passively transported outside the rack/cabinet to heat conveying elements, which may be located into a cooling chimney for passive transport outside the building, or to a heat exchanger, e.g. to heat up tap water or other buildings, which may reduce the need for external energy supply and thereby gives rise to further environmental benefits.

The above method and arrangement may be used to obtain reliable and adequate work temperature of electronic components without consuming additional power, e.g. for energising fans or producing pre-cooled air.

A decreased energy consumption for transfering surplus heat away, may result in less energy costs for the users, and may further be considered environmental friendly.

The passive, self-circulating system comprises no moving parts, and may thereby require less service and be more reliable. Lack of moving parts may further result in less noise and a more suitable working environment. Furthermore, transferring surplus heat away from the electronic components, may decrease the need of incorporated fans at the electronic components, which may decrease the manufacturing and service costs. Moreover, because incorporated fans are often controlled based on the needs for transferring surplus heat away, and moving parts give rise to vibrations, less need for transferring heat away, may result in that any fans applied is required to work less, which may give rise to less vibrations, less fatigue and increased life cycles for the electronic components.

Further features and benefits of the present invention will become apparent from the detailed description.

### BRIEF DESCRIPTION OF THE DRAWINGS

The present invention will now be described in more detail by means of exemplary embodiments and with reference to the accompanying drawings, in which:

FIG. 1 is an image showing an arrangement where heat is transferred away, according to prior art.

FIG. 2 is an image showing another arrangement where heat is transferred away, according to prior art.

FIG. 3 is an image illustrating an arrangement where heat is transferred away, in accordance with one embodiment.

FIG. 4a is an image illustrating an arrangement where heat is transferred away, in accordance with another embodiment.

FIG. 4b is an image illustrating an arrangement where heat is transferred away, in accordance with a further embodiment.

FIG. 5a-c are different views illustrating an arrangement for transferring heat away, in accordance with a further embodiment.

FIG. 6 is a flow chart illustrating a method for transferring heat away, in accordance with a further embodiment.

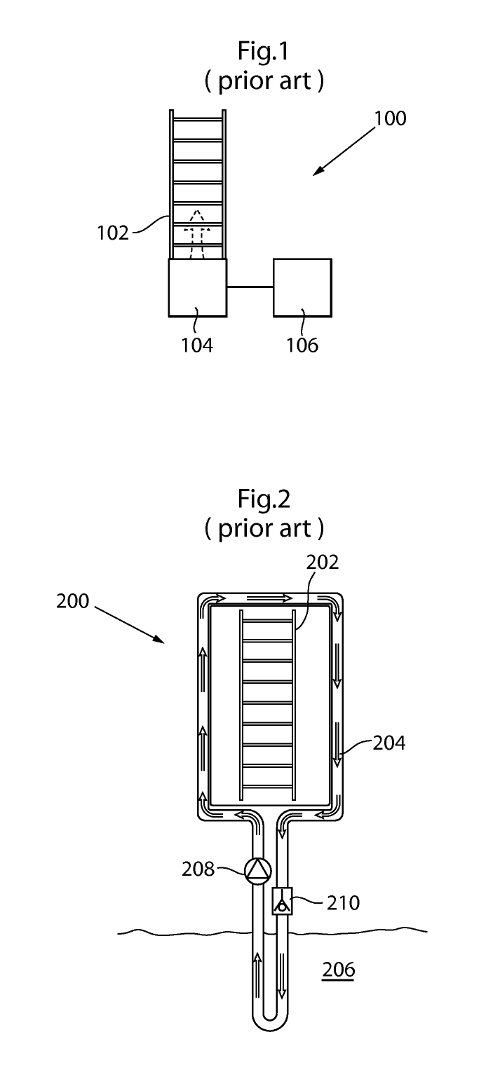

### DETAILED DESCRIPTION

Briefly described, the present invention provides a solution for optimising and achieving reliable working conditions for electronic component(s), especially electronic components arranged togetether in a rack, e.g. contained in a cabinet, by transfering surplus heat away. By arranging heat-pipes adjacent to, or in the rack/cabinet, the heat-pipes will absorb surplus heat and transfer to a heat conveying element, which conveys the surplus heat to an environment outside the rack/cabinet.

Heat-pipes are generally constructed as straight or looped types. Traditional heat-pipes have a limitation in the possibility of transporting large amounts of heat at any longer distance. Looped-heat-pipes don't have this limitation and as an example they are today used in aircrafts to transport heat from the engines in the multi kW range. A “standard” looped-heat-pipe evaporator with a diameter of 22 mm and a length of 300 mm can transport up to 1.2 kW.

Heat-pipes has been applied also in other technical areas. For cooling down food, a refridgerator comprising heat-pipes is known through the patent publication SU 1455180, A. However, the application is different and is directed to cooling down food for keeping it fresh, while the present invention instead is directed to transfering surplus heat away from electronic components, in order to achieve reliable working conditions.

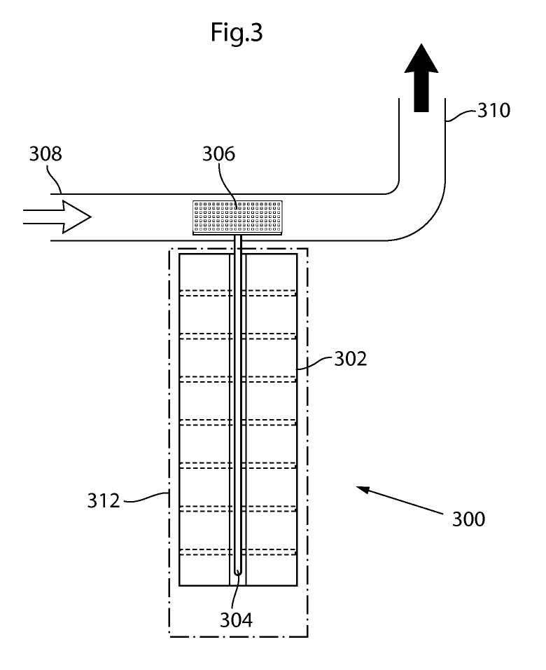

With reference to FIG. 3, an arrangement 300 with a rack 302 comprising at least one heat-pipe 304 for passively transferring surplus heat away will now be described, in accordance with an embodiment. At the rack 302 the heat-pipe(s) 304 are arranged, substantially vertical. The upper parts of the heat-pipe(s) 304 are connected to a cooling flange 306, which is adapted to convey the heat transfered by the heat-pipe(s) 304 to an air-flow (indicated with an un-filled arrow). The air-flow absorbs the heat (indicated with a filled arrow) from the cooling flange 306. In this embodiment the cooling flange 306 is arranged in a tube 308 with the air-flow, which transfers the heat to a cooling chimney 310. Arranging the cooling flange 306 in an airflow achieves an improved transferring of surplus heat away. Furthermore, as indicated above, the transferred heat may be taken care of, e.g. to be applied for warming up buildings etc.

However, the invention is not limited to the above described embodiment. A skilled person realises how to select a suitable heat conveying element, e.g. one or more cooling fins, cooling flanges, etc. Furthermore, he/she realises also how to arrange the heat-pipe(s) to achieve a reliable transfer of surplus heat away. For instance, the heat-pipe(s) does not need to be arranged completely vertical, but are to be arranged substanitially vertical to utilise the gravity force for achieving a circulation of the the cooling medium comprised in the heat-pipe(s), i.e. a uppward transfer of evaporised cooling medium and a downward transfer of condensated cooling medium. Moreover, even if straight heat-pipe(s) are employed in the embodiment, the invention is not limited thereto. The skilled person may easily select the number and type of heat-pipes, e.g. looped heat-pipes. The operation of heat-pipe(s) is wellknown and is therefore not necessary to be further described.

Moreover, even if the cooling flange 306 is arranged in a tube 308 with an air-flow in order to increase the amount of heat to be transferred away, in the above described embodiment, the arrangement of the cooling flange 306 may differ. For instance, the cooling flange 306 may be arranged in a free space above the rack 302, i.e. without any tube 308 or cooling chimney 310.

Furthermore, providing a cabinet 312 comprising electronic component(s), e.g. various cards in a base station, with the arrangement 300, will achieve a reliable environment for the electronic component(s).

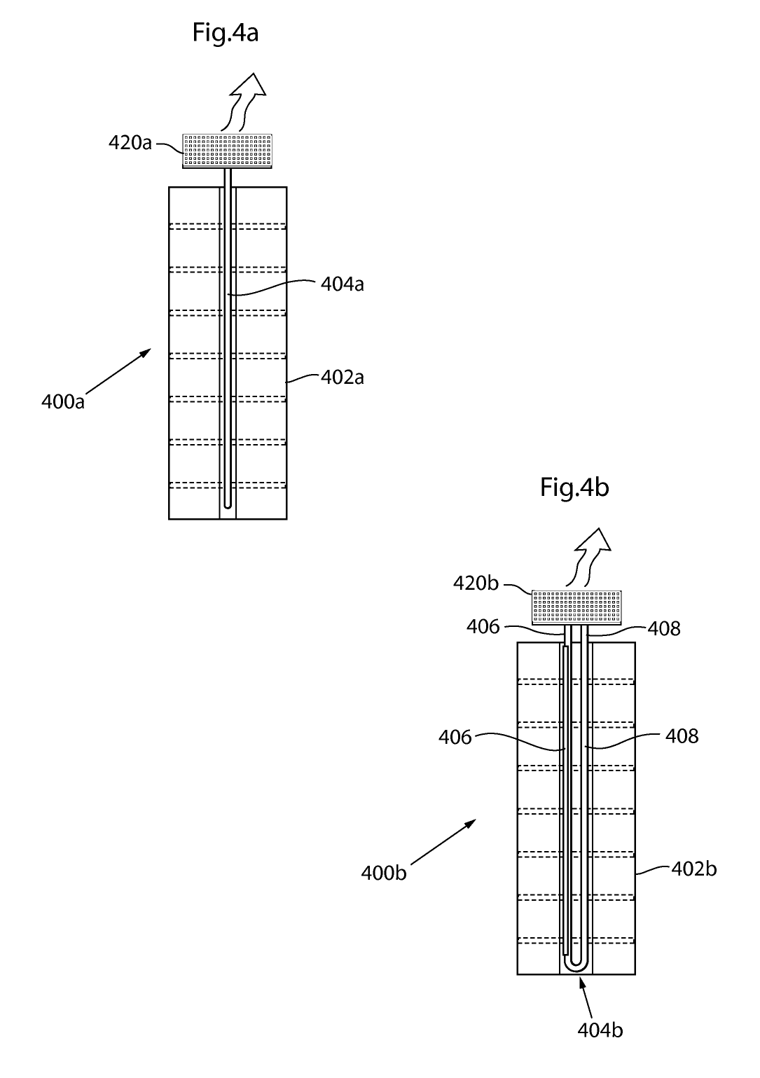

With reference to FIG. 4a, an arrangement 400a for transferring surplus heat away from a rack 402a applying at least one straight heat-pipe 404a will now be described, according to an embodiment.

In the arrangement 400a, electronic components (not reffered to), which typically generate surplus heat, are arranged in a rack 402a.Such electronic components may be realised as various cards in a base station for mobile communication, or other suitable electronic equipments, etc. The straight heat-pipe(s) 404a are arranged at the rack 402a, adjacent to the electronic components, and are adapted to transfer surplus heat away from the electronic components to a cooling flange 420a, where the heat is convected to an environment. Typically, each straight heat-pipe 404a absorbs surplus heat from its outside, and evaporises a cooling medium (not shown) comprised in the straight heat-pipe 404a. The pressure inside the straight heat-pipe(s) 404a is adjusted so that the absorbed surplus heat changes the phase of the cooling medium from liquid to gas. The evaporised cooling medium ascends in the straight heat-pipe(s) 404a and transfers thereby the surplus heat to the upper part of the straight heat-pipe(s) 404a, where the cooling flange 420a is arranged. The cooling flange 420a is adapted to convect the surplus heat to its environment, and therby also to condensate the cooling medium, i.e the cooling medium returns to liquid. The gravitational force transfers the condensated cooling medium, inside the straight heat-pipe(s) 404a, back to a lower part of the straight heat-pipe 404a(s), to absorb further surplus heat. In the described arrangement, the cooling medium is circulated inside the straight heat-pipe(s) 404a, driven by the gravitational force.

With reference to FIG. 4b, an arrangement 400b for transferring surplus heat away from a rack 402b applying at least one looped heat-pipe 404b will now be described, according to another embodiment.

In the arrangement 400b, electronic components (not referred to) which typically generates surplus heat are arranged, e.g. such electronic components as in the embodiment above. The looped heat-pipe(s) 404b are arranged in the rack 402b, adjacent to the electronic components, and are adapted to transfer surplus heat away from the electronic components to a cooling flange 420b, where it is convected to an environment. Typically, each looped heat-pipe 404b comprises an absorbing pipe 406 and an liquid transferring pipe 408. The absorbing pipe(s) 406 are adapted to absorb surplus heat from their outside and evaporise a cooling medium (not shown) comprised therein. The pressure inside the looped heat-pipe(s) 404b is adjusted so that the absorbed surplus heat changes the phase of the cooling medium from liquid to gas in the evaporising pipe(s) 406. The evaporised cooling medium ascends in the evaporising pipe(s) 406 and transfers thereby the surplus heat to the upper part of the looped heat-pipe(s) 404b, where the cooling flange 420b is arranged. The cooling flange 420b is adapted to convect the surplus heat to its environment, thereby condensating the cooling medium which returns to liquid. The gravitational force transfers the condensated cooling medium, inside the liquid transferring pipe(s) 408, back to a lower part of the heat-pipe(s) 404b, to absorb further surplus heat at the evaporising pipe(s) 406. In the described arrangement, the cooling medium is circulated in the looped heat-pipe(s), driven by the gravitational force, i.e. upwards in the evaporising pipe(s) 406 and downwards in the liquid transferring pipe(s) 408.

Typically, the evaporising pipe(s) 406 and the liquid transferring pipe(s) 408 are of different shape, where the evaporising pipe(s) 406 are designed to facilitate absorption of heat, and the liquid transferring pipe is designed to prevent absorption of heat.

A standard heat pipe is a two-phase heat transfer device with an extremely high effective thermal conductivity, and the inner surface along the pipe is lined with a capillary wicking material.

In a looped heat-pipe the wick structure is present only in the evaporising pipe. In order to prevent the liquid transferring pipe from absorbing surplus heat, it may be isolated on its outside.

Employing looped heat-pipe(s), enables the arrangement 404b to transfer a large amount of surplus heat away from the electronic components. As indicated above, a standard looped heat-pipe have the capacity to transport about 1 kW of surplus heat.

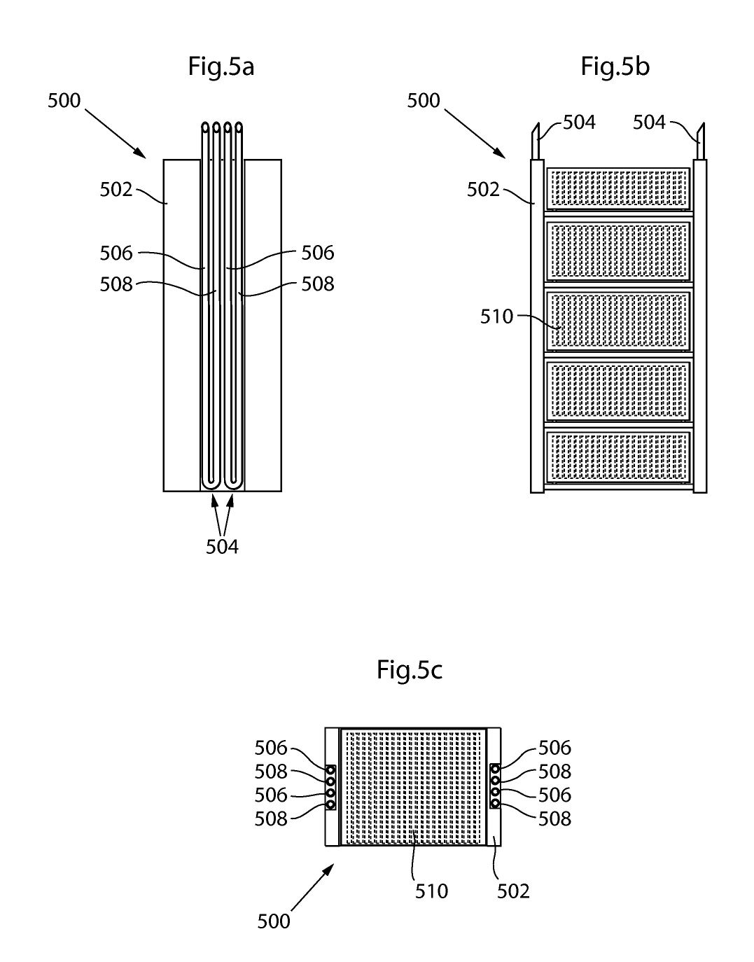

With reference to the FIGS. 5a-5c, an arrangement 500 for transferring surplus heat away from electronic components 510 arranged in a rack 502, in accordance with a further embodiment, will now be described.

FIG. 5a shows a side view the arrangement 500. The rack 502 comprises the electronic components 510 (hidden in the figure), and looped heat-pipes 504 are further arranged in the rack 502. Each looped heat-pipe 504 comprises a evaporising pipe 506 and a liquid transferring pipe 508, as described in an embodiment above. Furthermore, an upper part of the looped heat-pipes 504 is also connected to a cooling flange (not shown), which is also described in an embodiment above.

FIG. 5b shows a front view of the arrangent 500. As describe above the arrangent 500 comprises the rack 502, in which looped heat-pipes 504 are arranged. The evaporising pipes 506 and liquid transferring pipes 508 are hidden in this view. The electronic components 510 are shown in this view.

Furthermore, the FIG. 5c shows a cross-sectional view transversal through the arrangement 500. The evaporasing pipes 506 and the liquid transferring pipes 508 are arranged in the rack 502. The electronic components 510 are shown also in this view.

According to the above described embodiment, it is to be understood that the rack 502 may be contained in a cabinet, as described in another embodiment above.

In the above described embodiment, two looped heat-pipes are arranged at each side of the rack. However, a skilled person realises easily how to modify the arrangement by selecting a suitable alternative type and/or number of heat-pipes, e.g. looped or straight heat-pipes, within the concept. Furthermore, he/she realises also how to arrange the heat-pipes at the rack to achieve a relevant transferring of surplus heat away. He/she also realises that the arrangement can be used for transferring surplus heat away from a various number of electronic components, i.e. from a single one up to a suitable plurality.

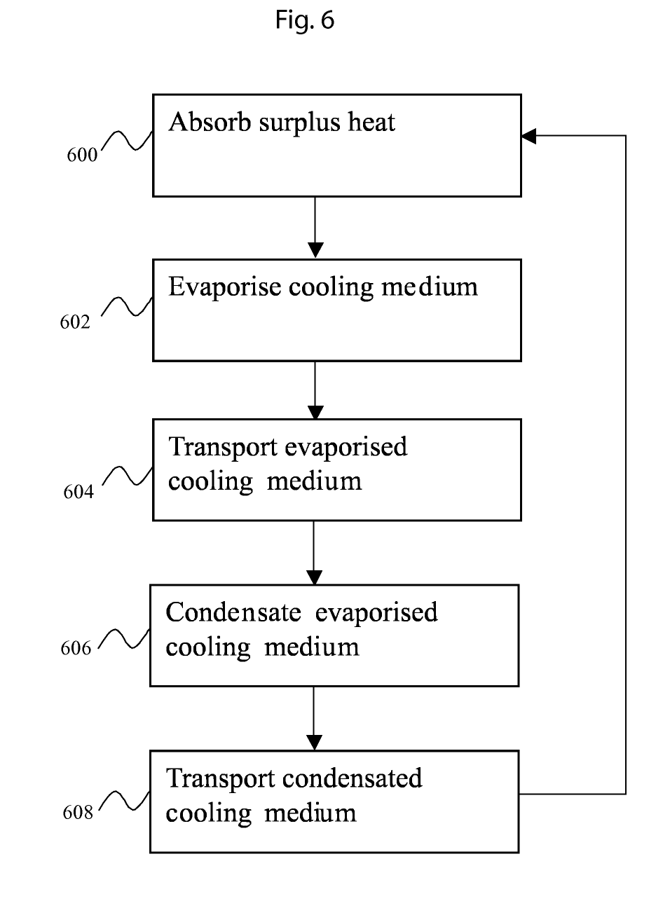

With reference to FIG. 6, a method for transferring surplus heat away from electronic components arranged in a rack and/or cabinet will now be described, in accordance with a further embodiment.

In a first step 600 one or more heat-pipes absorbs surplus heat generated by the electronic components. Due to the absorption of the surplus heat, a cooling medium contained in the heat-pipe(s) is evaporised in another step 602. In a following step 604, the evaporised cooling media is transported by self-circulation to a heat conveying element.

In a following step 606, the cooling medium is condensated, due to the fact that the surplus heat is conveyed to an environment outside the rack. In a final step 608, the condensated cooling medium is transported by self-circulation to the electronic component(s) to absorb further surplus heat. Typically, the cooling media is circulated in the heat-pipe, when the procedure according to the steps 600 to 608 is repeated.

The self-circulation described above is achieved by the gravity.

Moreover, it is to be understood that a skilled person realises how to combine characterising features of the above described embodiments, when designing an arrangement for transferring surplus heat away from electronic components comprised in a rack and/or cabinet. For instance, he/she may select which type of heat-pipes, heat conveying element, and cooling medium to apply, and how to arrange the heat-pipes, in order to achieve a relevant transferring of surplus heat away.

By transfering surplus heat away from a cabinet comprising electronic component(s), the component(s) get a better environment and better MTBF (Mean-Time Betweeen Failure values. At the same time passive heat transferring conserves energy related to cooling or venting out the heat generated by the component(s). The heat generated by the component(s) needs to be cooled or vented out is quite often around 80-90% of the energy consumed by the component(s). This can reduce CO2 footprint and the operators Operating Expenditures for energy.

Although procedures and and arrangements for passive heat transferring are adapted for communication network nodes in this description. The described procedures and arrangements can easily, as is realised by one skilled in the art, be adapted to be applied to any suitable electronic components, e.g. computer servers, etc.

The invention is generally defined by the following independent claims.

1.-12. (canceled)

13. An cooling apparatus at a rack for transferring surplus heat away from at least one heat generating electronic component arranged in the rack, the cooling apparatus comprising:
at least a first heat-pipe disposed adjacent to the electronic component;
a self-circulating cooling medium contained in the heat-pipe;
wherein the heat-pipe is unbranched and vertically aligned with the rack along a length of the heat-pipe;
wherein the heat-pipe extends along the whole vertical length of the rack;
wherein the cooling medium, in use, absorbs heat from the electronic component and transports the heat by self-circulation away from the electronic component through the heat-pipe.

14. The cooling apparatus of claim 13 wherein the heat-pipe is integrated in the rack.

15. The cooling apparatus of claim 13:
further comprising a heat conveying element;
wherein an upper part of the heat-pipe is associated with the heat conveying element;
wherein the heat conveying element is arranged to convey surplus heat from the cooling medium of the heat-pipe to an environment outside the rack.

16. The cooling apparatus of claim 13 wherein the rack is arranged in a cabinet.

17. The cooling apparatus of claim 13 wherein the heat-pipe is straight.

18. The cooling apparatus of claim 13 wherein the heat-pipe is looped.

19. The cooling apparatus of claim 13 wherein the cooling medium comprises at least one of: water, ammonia, carbon dioxide, acetone, nitrogen, methanol, and sodium.

20. The cooling apparatus of claim 13 wherein the self-circulation of the cooling medium is gravitationally induced.

21. The cooling apparatus of claim 1:
further comprising a second heat-pipe disposed adjacent to a second electronic component;
a second self-circulating cooling medium contained in the second heat-pipe;
wherein the second heat-pipe is unbranched and vertically aligned with the rack along a length of the second heat-pipe;
wherein the second heat-pipe extends along the whole vertical length of the rack;
wherein the second cooling medium, in use, absorbs heat from the second electronic component and transports the heat by self-circulation away from the electronic component through the second heat-pipe.

22. The cooling apparatus of claim 21 wherein the first and second cooling mediums are identical.

23. A method for transferring surplus heat away from at least one electronic component arranged in a rack, the method comprising:
absorbing, by at least a first heat-pipe, surplus heat from the electronic component;
evaporating a cooling medium contained in the heat-pipe;
transporting the evaporated cooling medium from the electronic component to a heat conveying element by self-circulation;
conveying the surplus heat to an environment outside the rack so as to condense the evaporated cooling medium at the heat conveying element;
transporting, by self-circulation, the condensed cooling medium to the electronic component;
thereafter, absorbing surplus heat from the electronic component by the condensed cooling medium.

24. The method of claim 23 wherein:
the transporting of the evaporated cooling medium is performed in a first part of the heat-pipe;
the transporting of the condensed cooling medium is performed in a second part of the heat-pipe, different from the first part.

25. The method of claim 23 wherein the transporting of the evaporated cooling medium and the transporting of the condensed cooling medium both occur in the same part of the heat-pipe.

26. The method of claim 23 wherein the self-circulation of the cooling medium is gravitationally induced.

27. The method of claim 23 wherein the at least a first heat-pipe comprises a plurality of heat-pipes.
